(19) United States
(12) Patent Application Publication
(10) Pub. No.: US 2007/0222027 A1
(43) Pub. Date: Sep. 27, 2007

(54) Electronic fuse elements with constricted neck regions that support reliable fuse blowing

(76) Inventors: Jeong-hwan Yang, Gyeonggi-do (KR); Yong-sang Cho, Gyeonggi-do (KR)

Correspondence Address: MYERS BIGEL SIBLEY & SAJOVEC, PO BOX 37428, RALEIGH, NC, 27627, US

(21) Appl. No.: 11/389,696

(22) Filed: Mar. 27, 2006

(51) Int. Cl. H01L 29/00

(52) U.S. Cl. 257/529

(57) ABSTRACT

Integrated circuit devices include a substrate and a fuse element on the substrate. The fuse element includes a metal pattern (e.g., dumbell-shaped) having a neck region therein that is sufficiently constricted to enable complete rupture of the neck region when the metal pattern in the fuse element is blown. A semiconductor region is also provided. This semiconductor region is electrically connected to the metal pattern on opposite sides of the neck region. The semiconductor region may be a polysilicon pattern having a shape equivalent to a shape of the metal pattern and the metal pattern contacts an upper surface of the polysilicon pattern. A first portion of the polysilicon pattern, which extends opposite the neck region, is undoped polysilicon and a second portion of the polysilicon pattern, which extends opposite a first end of the metal pattern, is doped polysilicon. The first portion of the polysilicon pattern provides a resistive path between first and second opposing ends of the metal pattern located on opposite sides of the neck region.

### FIELD OF THE INVENTION

The present invention relates to integrated circuit devices and, more particularly, to integrated circuit devices having fuse elements therein.

### BACKGROUND OF THE INVENTION

Many integrated circuit devices, including high capacity memory devices, utilize fuse elements as passive one-time programmable circuit devices. Many of the fuse elements contain metal regions that may be physically “blown” during semiconductor chip processing by using a laser cutting technique or electrically “blown” by establishing a very high current density within the fuse element for a sufficient duration to break an electrical connection provided by the metal region. In some cases, fuse elements on an integrated circuit chip may be electrically blown after packaging. As will be understood by those skilled in the art, an “unblown” fuse element may be treated as having a very low series resistance that represents one logic state (e.g., logic 0 (or 1)) and a “blown” fuse element may be treated as having an very large or possibly infinite series resistance that represents another logic state (logic 1 (or 0)). Examples of fuse elements are disclosed in U.S. Pat. No. 6,838,926 to Jung et al., entitled “Fuse Circuit for Semiconductor Integrated Circuit.” Additional examples of fuse elements are disclosed in: U.S. Pat. No. 6,960,978 to Leigh et al., entitled “Fuse Structure”; U.S. Pat. No. 6,984,549 to Manning, entitled “Methods of Forming Semiconductor Fuse Arrangements”; and U.S. Pat. No. 6,979,601 to Marr et al., entitled “Methods for Fabricating Fuses For Use in Semiconductor Devices and Semiconductor Devices Including Such Fuses.”

### SUMMARY OF THE INVENTION

Integrated circuit devices according to embodiments of the present invention include a substrate and a fuse element on the substrate. The fuse element includes a metal pattern (e.g., dumbell-shaped) having a neck region therein that is sufficiently constricted to enable complete rupture of the neck region when the metal pattern in the fuse element is blown. A semiconductor region is also provided. This semiconductor region is electrically connected to the metal pattern on opposite sides of the neck region. In some of these embodiments, the semiconductor region is a polysilicon pattern having a shape equivalent to a shape of the metal pattern and the metal pattern directly contacts an upper surface of the polysilicon pattern. In other embodiments of the present invention, a first portion of the polysilicon pattern, which extends opposite the neck region, is undoped polysilicon and a second portion of the polysilicon pattern, which extends opposite a first end of the metal pattern, is doped polysilicon. In these embodiments, the first portion of the polysilicon pattern provides a first resistive path between first and second opposing ends of the metal pattern located on opposite sides of the neck region. In still other embodiments of the present invention, portions of the polysilicon pattern collectively form a P-i-N diode within the semiconductor region.

### BRIEF DESCRIPTION OF THE DRAWINGS

FIG. 1 is a layout view of an electronic fuse element according to embodiments of the present invention.

FIG. 2A is a cross-sectional view of the electronic fuse element of FIG. 2B.

FIG. 2B is a layout view of the electronic fuse element of FIG. 1 after being blown.

FIG. 3 is a layout view of an electronic fuse element according to embodiments of the present invention.

FIG. 4A is a cross-sectional view of the electronic fuse element of FIG. 4B.

FIG. 4B is a layout view of the electronic fuse element of FIG. 3 after being blown.

### DETAILED DESCRIPTION OF PREFERRED EMBODIMENTS

The present invention now will be described more fully herein with reference to the accompanying drawings, in which preferred embodiments of the invention are shown. This invention may, however, be embodied in many different forms and should not be construed as being limited to the embodiments set forth herein; rather, these embodiments are provided so that this disclosure will be thorough and complete, and will fully convey the scope of the invention to those skilled in the art. Like reference numerals refer to like elements throughout.

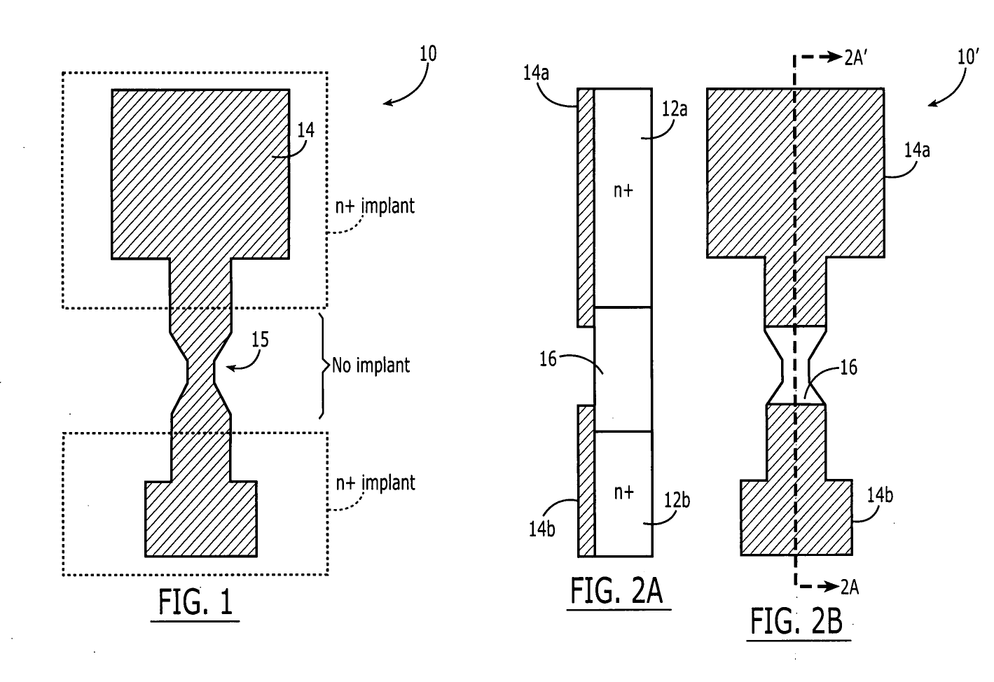

Referring now to FIGS. 1 and 2A-2B, an integrated circuit (IC) device according to embodiments of the invention includes at least one fuse element 10, which may be used as a one-time programmable switch. This programmable switch may reflect one digital logic state (e.g., logic “0” or “1”) when the fuse element is unblown (e.g., provides a “short” circuit) or another digital logic state when the fuse element is blown. This fuse element 10 includes a generally dumbell-shaped metal pattern 14 having a neck region 15 therein that is sufficiently constricted (i.e., tapered down to a relatively narrow line) to enable complete rupture of the neck region 15 when the metal pattern 14 in the fuse element 10 is blown. As will be understood by those skilled in the art, the metal pattern 14 may be blown in response to sufficient lateral migration of atoms within the neck region 15 caused by current crowding. This migration of atoms within the neck region 15 occurs when a lateral current having a sufficiently high current density is passed through the narrower neck region 15 during a fuse blowing operation. This current is passed from one end of the metal pattern to the other end of the metal pattern using external circuitry (not shown) connected to both ends of the fuse element 10. The fuse element 10 further includes a semiconductor region which underlies and contacts the metal pattern 14 along its length. As illustrated by FIGS. 1 and 2A-2B, this semiconductor region may be a dumbell-shaped polysilicon region having the same shape as the metal pattern 14. This fuse element 10 may be formed by a sequence of fabrication steps. These steps include depositing a layer of polysilicon and then selectively implanting a high concentration of dopants into portions of the layer of polysilicon using an implant mask to selectively block implantation. The regions that receive the dopants are illustrated in FIG. 1 by the highlighted regions labeled “N+ implant.” Thereafter, a metal layer is deposited directly on the layer of polysilicon and a layer of photoresist material is deposited on the metal layer. The layer of photoresist material is patterned (e.g., to define a dumbell-shaped mask pattern) and used as an etching mask when etching back the metal layer and polysilicon layer in sequence to define the fuse element 10.

Moreover, as illustrated by FIG. 2A, which shows the state of a blown fuse element 10′, the polysilicon region may include an N+ polysilicon region 12a underlying a first end of the metal pattern 14 and an N+ polysilicon region 12b underlying a second end of the metal pattern 14. These two polysilicon regions 12a and 12b are electrically connected together by an undoped (or very lightly doped) polysilicon region 16. This undoped polysilicon region 16 extends opposite the neck region 15 and remains connected to opposing ends of the metal pattern 14 after the metal pattern 14 within the fuse element is blown. These opposing ends of the metal pattern 14 are illustrated by the reference characters 14a and 14b. Because of this remaining electrical connection, the resistance between the opposing ends 14a and 14b is defined by a lateral resistance of the illustrated portion of the undoped polysilicon region 16, which may be relatively high. In this manner, the “open” or “closed” state of the fuse element (i.e., “blown” or “unblown”) may be detected by evaluating a lateral resistance of the fuse element (after programming) using surrounding circuit elements (not shown).

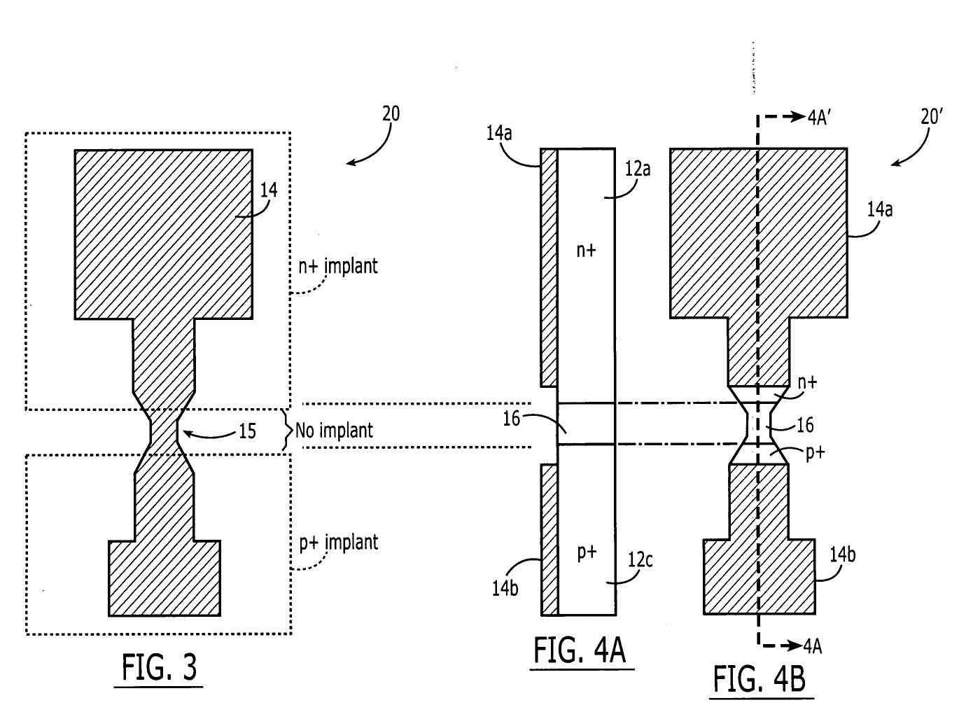

Referring now to FIGS. 3 and 4A-4B, fuse elements 20 according to other embodiments of the invention utilize a P-i-N polysilicon diode pattern instead of the N-i-N pattern illustrated by FIGS. 2A-2B. This P-i-N polysilicon pattern may be more suitable for unidirectional bias conditions where the N+ region 12a is biased at a higher voltage than the P+ region 12c. In FIGS. 4A-4B, the blown fuse element 20′ includes a relatively high resistivity path that extends within the undoped polysilicon region 16.

In the drawings and specification, there have been disclosed typical preferred embodiments of the invention and, although specific terms are employed, they are used in a generic and descriptive sense only and not for purposes of limitation, the scope of the invention being set forth in the following claims.

That which is claimed is:

1. An integrated circuit device, comprising:
a substrate; and
a fuse element on said substrate, said fuse element comprising:
a metal pattern having a neck region therein that is sufficiently constricted to enable complete rupture of the neck region when the metal pattern in said fuse element is blown; and
a semiconductor region electrically connected to the metal pattern on opposite sides of the neck region.

2. The integrated circuit device of claim 1, wherein said semiconductor region is a polysilicon pattern having a shape equivalent to a shape of the metal pattern.

3. The integrated circuit device of claim 2, wherein the metal pattern contacts an upper surface of the polysilicon pattern.

4. The integrated circuit device of claim 2, wherein a first portion of the polysilicon pattern extending opposite the neck region is undoped polysilicon.

5. The integrated circuit device of claim 4, wherein a second portion of the polysilicon pattern extending opposite a first end of the metal pattern is doped polysilicon.

6. The integrated circuit device of claim 4, wherein the first portion of the polysilicon pattern provides a first resistive path between first and second opposing ends of the metal pattern located on opposite sides of the neck region.

7. The integrated circuit device of claim 4, wherein a second portion of the polysilicon pattern extending opposite a first end of the metal pattern is N-type polysilicon; and wherein a third portion of the polysilicon pattern extending opposite a second end of the metal pattern is P-type polysilicon.

8. The integrated circuit device of claim 7, wherein the first, second and third portions of the polysilicon pattern collectively form a P-i-N diode within the semiconductor region.

9. An integrated circuit device, comprising:
a semiconductor substrate; and
a fuse element on said substrate, said fuse element comprising:
a dumbell-shaped metal pattern having a neck region therein that is sufficiently constricted to enable complete rupture of the neck region when the metal pattern in said fuse element is blown; and
a dumbell-shaped polysilicon region electrically contacting a primary surface of the dumbell-shaped metal pattern, said dumbell-shaped polysilicon region providing a resistive path between first and second opposing ends of the dumbell-shaped metal pattern when dumbell-shaped metal pattern within said fuse element is blown.

10. The integrated circuit device of claim 9, wherein the dumbell-shaped polysilicon region comprises doped and undoped regions therein.

11. The integrated circuit device of claim 10, wherein the resistive path is provided through the undoped region when the dumbell-shaped metal pattern within said fuse element is blown.
